(19) United States
(12) Patent Application Publication
(10) Pub. No.: US 2014/0083750 A1
(43) Pub. Date: Mar. 27, 2014

(54) RAW GLASS PLATE FOR MANUFACTURING TOUCH PANEL AND METHOD OF MANUFACTURING TOUCH PANEL USING RAW GLASS PLATE

(71) Applicant: SAMSUNG ELECTRO-MECHANICS CO., LTD., Suwon (KR)

(72) Inventors: Kyoung Soo Chae, Suwon (KR); In Hyun Jang, Suwon (KR); Seul Gi Kim, Suwon (KR); Yun Ki Hong, Suwon (KR); Seung Joo Shin, Suwon (KR); Jang Ho Park, Suwon (KR)

(73) Assignee: SAMSUNG ELECTRO-MECHANICS CO., LTD., Suwon (KR)

(21) Appl. No.: 13/717,631

(22) Filed: Dec. 17, 2012

(30) Foreign Application Priority Data
Sep. 21, 2012 (KR) 10-2012-0105399

(51) Int. Cl. H05K 1/03; H05K 1/09; H05K 3/10

(52) U.S. Cl. CPC H05K 1/0306; H05K 3/10; H05K 1/09
USPC 174/257; 29/846; 174/258

(57) ABSTRACT

Disclosed herein are a raw glass plate for manufacturing a touch panel and a method of manufacturing a touch panel using the raw glass plate. The raw glass plate includes a unit substrate region divided into an active region and a non-active region that is an edge portion of the active region; electrodes formed on the active region of the unit substrate region; wirings that are formed on the non-active region of the unit substrate region and are electrically connected to the electrodes; and a guard line that is formed outside a position at which the wirings are formed, on the non-active region of the unit substrate region in a longitudinal direction of the wirings.

### CROSS REFERENCE TO RELATED APPLICATION

This application claims the benefit of Korean Patent Application No. 10-2012-0105399, filed on Sep. 21, 2012, entitled “Raw Glass Plate for Manufacturing Touch Panel and Method of Manufacturing Touch Panel Using Raw Glass Plate”, which is hereby incorporated by reference in its entirety into this application.

### BACKGROUND OF THE INVENTION

1. Technical Field

The present invention relates to a raw glass plate for manufacturing a touch panel and a method of manufacturing a touch panel using the raw glass plate.

2. Description of the Related Art

As computers using digital technologies have been developed, auxiliary equipment of computers has correspondingly been developed together. A personal computer, a portable transmitting apparatus, or other personal information processing apparatuses perform text and graphic processes by using various input devices such as a keyboard, a mouse, and the like.

However, along with the rapid development of an information-oriented society, computers have been widely used, and thus, it is difficult to effectively drive a product by using only a keyboard and a mouse, which presently function as an input device. Accordingly, there is an increasing need for a device to which anyone easily can easily input information via a simple method without mishandling.

Technologies for input devices have exceeded the standard for providing general functions and interest in input devices has changed toward high reliability, high durability, high innovation, design and process-related technologies. To this end, a touch panel has been developed as an input device for inputting information such as text, graphic, and so on.

A touch panel is a device that is installed on a display surface of a flat display apparatus such as an electronic notebook, a liquid crystal display device (LCD), a plasma display panel (PDP), or electroluminescence (EL) or a display surface of an image displaying apparatus such as a cathode ray tube (CRT) and is used for a user to select desired information while watching the image displaying apparatus.

A touch panel is classified into a resistive type touch panel, a capacitive type touch panel, an electro-magnetic type touch panel, a surface acoustic wave (SAW) type touch panel, and an infrared type touch panel. Such various types of touch panels are used in electronic products in consideration of issues of signal amplification, a resolution difference, difficulty in design and process technologies, optical properties, electrical properties, mechanical properties, environmental properties, input properties, durability, and economic feasibility. Currently, from among various types of touch panels, a resistive type touch panel and a capacitive type touch panel have been most commonly used.

An example of a conventional touch panel is disclosed in Korean Patent Laid-Open Publication No. 10-2011-0132761.

As disclosed in Korean Patent Laid-Open Publication No. 10-2011-0132761, a conventional touch panel is configured in such a way that an electrode for detecting a capacitance variation may be formed on an active region of a transparent substrate. In addition, the touch panel includes a wiring that is electrically connected to the electrode in order to transmit a signal generated by the electrode to a controller. Here, the wiring is formed on a non-active region of the transparent substrate.

Recently, the transparent substrate has been used as a window that is disposed at an outermost portion of a touch panel in order to make the touch panel thinner. That is, the electrode and the wiring are formed directly on the window.

A method of manufacturing the touch panel includes preparing a raw glass plate, forming a conductive layer including the electrode and the wiring on a plurality of unit transparent substrates divided from the raw glass plate, and forming a plurality of transparent substrates whereon the conductive layer is formed by cutting the raw glass plate into the unit transparent substrates.

In this case, during the formation of the conductive layer, the wiring is formed on the non-active region of the unit transparent substrate, as described above. Herein, an outer line of the non-active region is a line along which the cutting is performed. Thus, the wiring formed on the non-active region is positioned adjacent to the line along which the cutting is performed.

The wiring formed in the above-described way is easily damaged if particles of the raw glass plate, which is formed during the cutting of the raw glass plate into the unit transparent substrates, collide with the wiring or if high-temperature heat generated due to friction, which is generated during the cutting, is transferred to the wiring. In this case, a touch signal generated from the electrode is not accurately transferred to the controller due to the damage to wiring, and accordingly, the controller of the touch panel cannot accurately detect a touch position.

Accordingly, there is a need to overcome the problem in terms of damage to wiring during the manufacture of a touch panel. However, a conventional touch panel cannot overcome the problem yet.

### SUMMARY OF THE INVENTION

The present invention has been made in an effort to provide a raw glass plate for manufacturing a touch panel for preventing damage to wiring during the manufacture of the touch panel, and a method of manufacturing a touch panel using the raw glass plate.

According to a first preferred embodiment of the present invention, there is provided a raw glass plate for manufacturing a touch panel, including a unit substrate region divided into an active region and a non-active region that is an edge portion of the active region; electrodes formed on the active region of the unit substrate region; wirings that are formed on the non-active region of the unit substrate region and are electrically connected to the electrodes; and a guard line that is formed outside a position at which the wirings are formed, on the non-active region of the unit substrate region in a longitudinal direction of the wirings.

In the raw glass plate for manufacturing the touch panel, the wirings may include copper (Cu), aluminum (Al), gold (Au), silver (Ag), titanium (Ti), palladium (Pd), chromium (Cr), a combination thereof.

In the raw glass plate for manufacturing the touch panel, the wirings may include metallic silver formed by exposing/developing a silver salt emulsion layer.

In the raw glass plate for manufacturing the touch panel, the guard line may include copper (Cu), aluminum (Al), gold (Au), silver (Ag), titanium (Ti), palladium (Pd), chromium (Cr), or a combination thereof.

In the raw glass plate for manufacturing the touch panel, the guard line may include metallic silver formed by exposing/developing a silver salt emulsion layer.

In the raw glass plate for manufacturing the touch panel, the wirings and the guard line may be made of the same material.

In the raw glass plate for manufacturing the touch panel, the guard line may be spaced apart from the wirings.

In the raw glass plate for manufacturing the touch panel, branch lines extending from the guard line may be connected to the wirings such that the guard line is electrically connected to the wirings.

According to a second preferred embodiment of the present invention, there is provided a method of manufacturing a touch panel using a raw glass plate for manufacturing a touch panel, including: (A) preparing a raw glass plate having a unit substrate region; (B) forming electrodes on an active region of the unit substrate region; (C) forming wirings on a non-active region that is an edge portion of the active region of the unit substrate region; (D) forming a guard line outside a position at which the wirings are formed, on the non-active region of the unit substrate region in a longitudinal direction of the wirings; and (E) cutting the raw glass plate into the unit substrate regions.

In step (C), the wirings may be formed by plating or depositing metal including copper (Cu), aluminum (Al), gold (Au), silver (Ag), titanium (Ti), palladium (Pd), chromium (Cr), or a combination thereof.

In step (C), the wirings may be formed by exposing/developing a silver salt emulsion layer.

In step (D), the guard line may be formed by plating or depositing metal including copper (Cu), aluminum (Al), gold (Au), silver (Ag), titanium (Ti), palladium (Pd), chromium (Cr), or a combination thereof.

In step (D), the guard line may be formed by exposing/developing a silver salt emulsion layer.

Steps (C) and (D) may be simultaneously performed such that the wirings and the guard line are made of the same material.

In step (D), the guard line may be formed so as to be spaced apart from the wirings.

In step (D), the guard line may be formed so as to be electrically connected to the wirings.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a raw glass plate for manufacturing a touch panel, according to an embodiment of the present invention;

FIG. 2 is an enlarged plan view of a main portion of the raw glass plate of FIG. 1, according to an embodiment of the present invention;

FIG. 3 is an enlarged plan view of a main portion of a raw glass plate whereon a conductive layer and a guard line are formed on a unit substrate region shown in FIG. 1, according to an embodiment of the present invention;

FIG. 4 is an enlarged view of a portion ‘A’ shown in FIG. 3, according to an embodiment of the present invention;

FIG. 5 is an enlarged view of a portion ‘A’ shown in FIG. 3, according to another embodiment of the present invention; and

FIG. 6 is a cross-sectional view of a unit substrate formed by cutting the unit substrate region shown in FIG. 3, according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

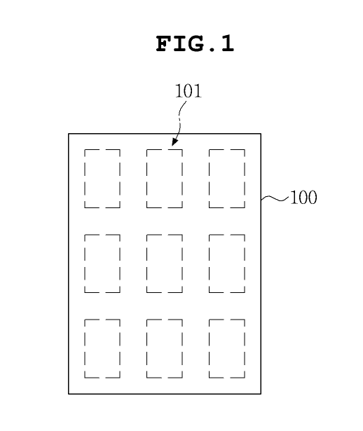

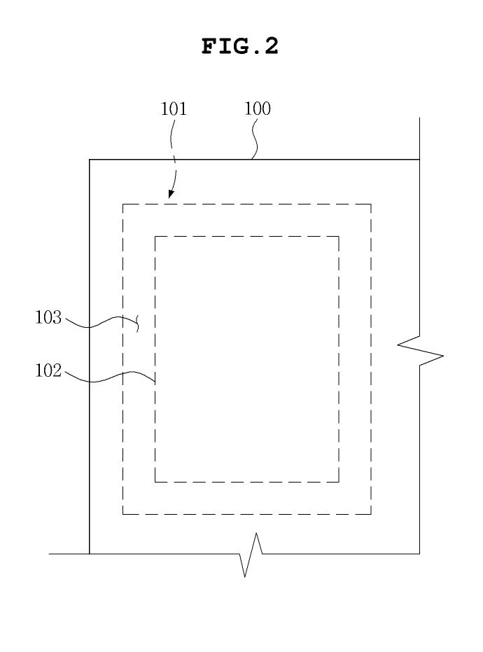

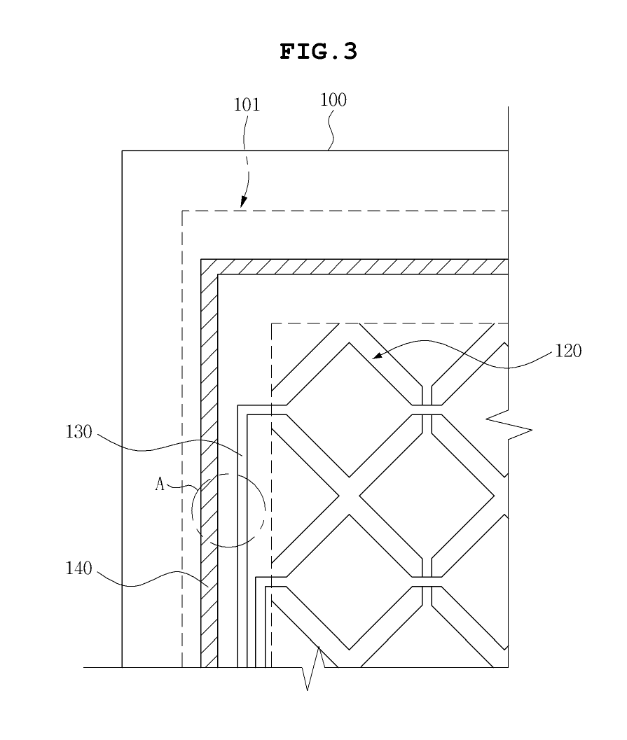

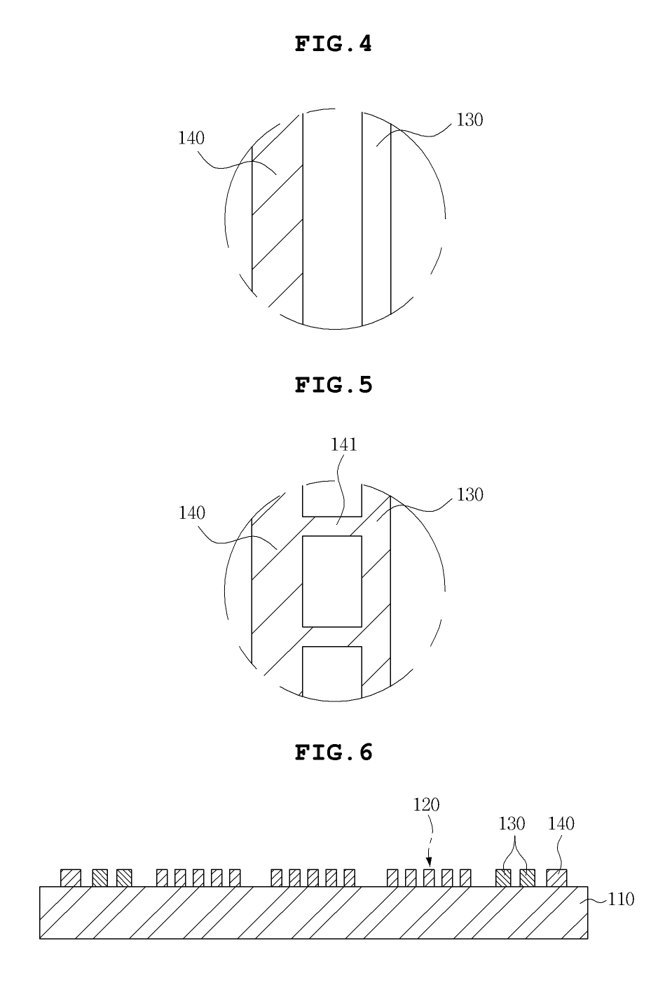

FIG. 1 is a plan view of a raw glass plate 100 for manufacturing a touch panel, according to an embodiment of the present invention. FIG. 2 is an enlarged plan view of a main portion of the raw glass plate 100 of FIG. 1, according to an embodiment of the present invention. FIG. 3 is an enlarged plan view of a main portion of the raw glass plate 100 whereon a conductive layer and a guard line 140 are formed on a unit substrate region 101 shown in FIG. 1, according to an embodiment of the present invention. FIG. 4 is an enlarged view of a portion ‘A’ shown in FIG. 3, according to an embodiment of the present invention. FIG. 5 is an enlarged view of a portion ‘A’ shown in FIG. 3, according to another embodiment of the present invention. FIG. 6 is a cross-sectional view of a unit substrate 110 formed by cutting the unit substrate region 101 shown in FIG. 3, according to an embodiment of the present invention.

As shown in FIGS. 1 through 3, the raw glass plate 100 for manufacturing the touch panel according to an embodiment of the present invention includes the unit substrate region 101 divided into an active region 102 and a non-active region 103 corresponding to an edge portion of the active region 102, electrodes 120 formed on the active region 102 of the unit substrate region 101, wirings 130 that are formed on the non-active region 103 of the unit substrate region 101 and are electrically connected to the electrodes 120, and the guard line 140 that is formed outside a position at which the wirings 130 are formed, on the non-active region 103 of the unit substrate region 101 in a longitudinal direction of the wirings 130.

As shown in FIG. 1, the raw glass plate 100 may be divided into one or more unit substrate regions 101. The unit substrate regions 101 may be obtained by dividing the raw glass plate 100 via a cutting process of the raw glass plate 100 as described below. In addition, as shown in FIG. 6, the unit substrate 110 may be used as a touch panel substrate.

The touch panel substrate provides a region on which the conductive layer and the guard line 140 are formed, which will be described below. The touch panel substrate needs to have bearing capacity for supporting the conductive layer and the guard line 140 and transparency whereby a user recognizes an image provided by an image displaying apparatus.

In consideration of the bearing capacity and the transparency, the touch panel substrate may be made of glass or tempered glass. The touch panel substrate may be a window disposed at an outermost portion of the touch panel. In this case, since the conductive layer that will be described below is formed directly on the window, processes for forming the conductive layer on a separate substrate and attaching the conductive layer to the window may be omitted during manufacture of the touch panel, and a total thickness of the touch panel may be reduced.

Thus, according to the present embodiment, the raw glass plate 100 may be used as a raw material for providing the touch panel substrate in order to provide the touch panel substrate used as a window.

In addition, the raw glass plate 100 may be activated via high-frequency treatment or primer treatment. Since the raw glass plate 100 is processed in this way, when the conductive layer and the guard line 140 are formed on the raw glass plate 100, the adhesion between the raw glass plate 100 and the conductive layer and the guard line 140 may be further enhanced.

As shown in FIG. 2, the unit substrate region 101 may be divided into the active region 102 and the non-active region 103 disposed outside an edge of the active region 102. The active region 102 is a region to which a touch is input by a user and is a screen region from which the user visually checks an operation of the touch panel. In addition, the non-active region 103 is a region that is hidden by a black or white bezel portion (not shown) formed on an edge portion of the window and is not exposed outside the touch panel.

As shown in FIG. 3, the conductive layer may include the electrodes 120 and the wirings 130. The electrodes 120 may generate a signal when the user touches the touch panel such that a controller (not shown) may recognize touch coordinates. The signal generated by the electrodes 120 is transmitted to a controller (not shown) through the wirings 130 that will be described below.

The electrodes 120 may be made of any one of copper (Cu), aluminum (Al), gold (Au), silver (Ag), titanium (Ti), palladium (Pd), and chromium (Cr) or a combination thereof. Alternatively, the electrodes 120 may be made of metallic silver formed by exposing/developing a silver salt emulsion layer. In this case, the electrodes 120 may be formed in a mesh pattern.

In addition, the electrodes 120 may be made of a conductive polymer. Here, examples of the conductive polymer may include poly-3,4-ethylenedioxythiophene/polystyrene sulfonate (PEDOT/PSS), polyaniline, polyacetylene, or poly-phenylenevinylene. In addition, the electrodes 120 may include metal oxide. Here, the metal oxide may include indium-tin oxide. In this case, the electrodes 120 may each have a plate shape.

As described above, the wirings 130 may transmit the signal generated from the electrodes 120 to the controller. In more detail, the unit substrate 110 (see FIG. 6) obtained by cutting the unit substrate region 101 may be connected to a flexible printed circuit board (FPCB) that may be connected to connection terminals formed at ends of the wirings 130. Thus, the signal generated from the electrodes 120 may be transmitted to the controller through the wirings 130 and the FPCB. In general, the wirings 130 may each have a straight line shape. Since the wirings 130 do not have corresponding shapes to those of the electrodes 120, the wirings 130 are not formed on the active region 102 of the unit substrate region 101. In general, the wirings 130 are formed on the non-active region 103. As described above, since the wirings 130 formed on the non-active region 103 is hidden by the bezel portion formed on the edge portion of the window, the wirings 130 may not be viewed outside the touch panel.

The wirings 130 may be made of any one of Cu, Al, Au, Ag, Ti, Pd, and Cr or a combination thereof. Alternatively, the wirings 130 may be made of metallic silver formed by exposing/developing a silver salt emulsion layer. When the wirings 130 are made of these materials, if the wirings 130 are made of the same material as the electrodes 120, the wirings 130 and the electrodes 120 may be simultaneously formed via a single process.

As shown in FIG. 3, since the wirings 130 are formed on the non-active region 103, the wirings 130 are positioned adjacent to an outermost line of the non-active region 103, that is, an outermost line of the unit substrate region 101. In this case, the outermost line of the unit substrate region 101 may be a line along which the raw glass plate 100 is cut, which will be described below. Thus, the wirings 130 may easily collide with particles formed during the cutting of the unit substrate region 101. In this case, the wirings 130 may be damaged due to the collision of particles. In addition, heat generated during the cutting of the unit substrate region 101 may be easily transmitted to the wirings 130. Even in this case, the wirings 130 may be easily damaged due to the heat.

Accordingly, according to the present embodiment, in order to prevent damage to the wirings 130, the guard line 140 is formed on the unit substrate region 101 to protect the wirings 130.

As shown in FIG. 3, the guard line 140 is formed between the wirings 130 and the outermost line of the unit substrate region 101, which is a cutting line, so as to protect the wirings 130.

In detail, the guard line 140 may be formed on the non-active region 103 and may be formed outside the wirings 130. In this case, the guard line 140 may be spaced apart from the wirings 130 or may be formed adjacent to the wirings 13Q such that the guard line 140 is not almost spaced apart from the wirings 130.

In this case, the guard line 140 may be formed in a longitudinal direction of the wirings 130. In this case, as shown in FIGS. 3 and 4, the guard line 140 may be formed in a longitudinal direction of the wirings 130, but the present embodiment is not limited thereto.

In addition, the guard line 140 may be formed to have a length that is almost equal to or greater than a total length of the wirings 130 so as to protect the entire wirings 130. Alternatively, the guard line 140 does not have to have this length. For example, the guard line 140 may be formed to have a length corresponding to a portion of the wirings 130 so as to protect only a necessary portion of the wirings 130.

The guard line 140 may be made of any one of Cu, Al, Au, Ag, Ti, Pd, and Cr, or a combination thereof. Alternatively, the guard line 140 may be made of metallic silver formed by exposing/developing a silver salt emulsion layer. When the guard line 140 is made of these materials, if the guard line 140 is made of the same material as the wirings 130, the guard line 140 and the wirings 130 may be simultaneously formed via a single process. As described above, when the electrodes 120 and the wirings 130 are made of the same material via a single process, and the guard line 140 is made of the same material as the electrodes 120 and the wirings 130, the electrodes 120, the wirings 130, and the guard line 140 may be simultaneously formed by a single process.

When the guard line 140 is made of an electrical conductive material like the wirings 130, the guard line 140 may be electrically connected to the wirings 130.

In detail, as shown in FIG. 5, when the guard line 140 is spaced apart from the wirings 130, the guard line 140 may include branch lines 141 that extend from the guard line 140. In addition, the branch lines 141 are connected to the wirings 130, and thus, the guard line 140 may be electrically connected to the wirings 130 through the branch lines 141. In this case, electrical resistance of a corresponding wiring 130 that is electrically connected to the guard line 140 may be reduced.

In addition, the wirings 130 are less affected by heat generated during cutting of the unit substrate region 101. In other words, the guard line 140 may have an increased surface area due to the branch lines 141, thereby enhancing heat dissipating performance. The heat generated during cutting of the unit substrate region 101 is first transmitted to the guard line 140. In this regard, an entire surface area of the guard line 140 is increased due to the branch lines 141 included in the guard line 140, and thus, the heat may be sufficiently dissipated from the guard line 140. Accordingly, heat generated during cutting of the unit substrate region 101 may be less transmitted to the wirings 130, thereby preventing damage to the wirings 130 due to heat.

Hereinafter, a method of manufacturing a touch panel using the raw glass plate 100 for manufacturing the touch panel according to the aforementioned embodiment will be described. However, a repeated explanation thereof will not be given.

The method of manufacturing the touch panel using the raw glass plate 100 for manufacturing the touch panel according to the present embodiment includes (A) preparing the raw glass plate 100 having the unit substrate region 101, (B) forming the electrodes 120 on the active region 102 of the unit substrate region 101, (C) forming the wirings 130 on the non-active region 103 that is an edge portion of the active region 102 of the unit substrate region 101, (D) forming the guard line 140 outside a position at which the wirings 130 are formed, on the non-active region 103 of the unit substrate region 101 in a longitudinal direction of the wirings 130, and (E) cutting the raw glass plate 100 into the unit substrate regions 101.

In step (A), the raw glass plate 100 shown in FIG. 1 is prepared. The raw glass plate 100 may be divided into one or more unit substrate regions 101.

In steps (B) and (C), the conductive layer is formed on the unit substrate region 101. The conductive layer includes the electrodes 120 and the wirings 130.

In step (B), the electrodes 120 are formed on the active region 102 of the unit substrate region 101, as shown in FIG. 3. The electrodes 120 may be made of any one of metals such as Cu, Al, Au, Ag, Ti, Pd, and Cr or a combination thereof via plating or deposition. Alternatively, the electrodes 120 may be formed by exposing/developing a silver salt emulsion layer. In addition, the electrodes 120 may be made of a conductive polymer such as poly-3,4-ethylenedioxythiophene/polystyrene sulfonate (PEDOT/PSS), polyaniline, polyacetylene, or poly-phenylenevinylene, or a metal oxide such as indium-tin oxide by using a dry process, a wet process, or a direct patterning process.

In step (C), the wirings 130 are formed on the non-active region 103 of the unit substrate region 101, as shown in FIG. 3. The wirings 130 may be made of any one of metals such as Cu, Al, Au, Ag, Ti, Pd, and Cr or a combination thereof via plating or deposition. Alternatively, the wirings 130 may be formed by exposing/developing a silver salt emulsion layer.

In step (D), the guard line 140 is formed outside a position at which the wirings 130 are formed, on the non-active region 103 of the unit substrate region 101, as shown in FIG. 3. The guard line 140 may be made of any one of metals such as Cu, Al, Au, Ag, Ti, Pd, and Cr or a combination thereof via plating or deposition. Alternatively, the guard line 140 may be formed by exposing/developing a silver salt emulsion layer.

The guard line 140 may be formed in a longitudinal direction of the wirings 130 and may be spaced apart from the wirings 130. In this case, the guard line 140 may further include the branch lines 141 (see FIG. 5) that extend from the guard line 140 and may be electrically connected to the wirings 130 such that the branch lines 141 may be connected to the wirings 130.

Steps (C) and (D) may be simultaneously performed by a single process. That is, when the wirings 130 and the guard line 140 are made of the same metal material, the wirings 130 and the guard line 140 may be simultaneously formed by a single process such as plating or deposition. In addition, when the wirings 130 and the guard line 140 are made of the same silver salt emulsion layer, the wirings 130 and the guard line 140 may also be simultaneously formed by a single process of coating and exposing/developing the silver salt emulsion layer.

Furthermore, when the electrodes 120 are made of the above-described metal material or a silver salt emulsion layer, the electrodes 120, the wirings 130, and the guard line 140 may also be simultaneously formed via a single process.

In step (E), the raw glass plate 100 is cut into the unit substrate regions 101. As shown in FIG. 6, the cut unit substrate region 101 may be the unit substrate 110 that may be used as a touch panel substrate. The touch panel substrate may be, for example, a window that is disposed at an outermost portion of the touch panel.

According to the preferred embodiments of the present invention, a guard line is further formed outside wirings, thereby preventing particles formed during cutting of a raw glass plate from colliding with the wirings. In addition, heat generated during the cutting of the raw glass plate is transmitted to the guard line and is dissipated from the guard line. Thus, the wirings are less affected by the heat generated during the cutting of the raw glass plate. Accordingly, damage to the wirings due to collision of particles or heat may be prevented.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A raw glass plate for manufacturing a touch panel, comprising:
a unit substrate region divided into an active region and a non-active region that is an edge portion of the active region;
electrodes formed on the active region of the unit substrate region;
wirings that are formed on the non-active region of the unit substrate region and are electrically connected to the electrodes; and
a guard line that is formed outside a position at which the wirings are formed, on the non-active region of the unit substrate region in a longitudinal direction of the wirings.

2. The raw glass plate for manufacturing a touch panel as set forth in claim 1, wherein the wirings is made of copper (Cu), aluminum (Al), gold (Au), silver (Ag), titanium (Ti), palladium (Pd), chromium (Cr), or a combination thereof.

3. The raw glass plate for manufacturing a touch panel as set forth in claim 1, wherein the wirings are made of metallic silver formed by exposing/developing a silver salt emulsion layer.

4. The raw glass plate for manufacturing a touch panel as set forth in claim 1, wherein the guard line is made of copper (Cu), aluminum (Al), gold (Au), silver (Ag), titanium (Ti), palladium (Pd), chromium (Cr), or a combination thereof.

5. The raw glass plate for manufacturing a touch panel as set forth in claim 1, wherein the guard line is made of metallic silver formed by exposing/developing a silver salt emulsion layer.

6. The raw glass plate for manufacturing a touch panel as set forth in claim 1, wherein the wirings and the guard line are made of the same material.

7. The raw glass plate for manufacturing a touch panel as set forth in claim 1, wherein the guard line is spaced apart from the wirings.

8. The raw glass plate for manufacturing a touch panel as set forth in claim 7, wherein branch lines extending from the guard line are connected to the wirings such that the guard line is electrically connected to the wirings.

9. A method of manufacturing a touch panel, comprising:
(A) preparing a raw glass plate having a unit substrate region;
(B) forming electrodes on an active region of the unit substrate region;
(C) forming wirings on a non-active region that is an edge portion of the active region of the unit substrate region;
(D) forming a guard line outside a position at which the wirings are formed, on the non-active region of the unit substrate region in a longitudinal direction of the wirings; and
(E) cutting the raw glass plate into the unit substrate regions.

10. The method as set forth in claim 9, wherein in step (C), the wirings are formed by plating or depositing metal including copper (Cu), aluminum (Al), gold (Au), silver (Ag), titanium (Ti), palladium (Pd), chromium (Cr), or a combination thereof.

11. The method as set forth in claim 9, wherein in step (C), the wirings are formed by exposing/developing a silver salt emulsion layer.

12. The method as set forth in claim 11, wherein in step (D), the guard line is formed by plating or depositing metal including copper (Cu), aluminum (Al), gold (Au), silver (Ag), titanium (Ti), palladium (Pd), chromium (Cr), or a combination thereof.

13. The method as set forth in claim 11, wherein in step (D), the guard line is formed by exposing/developing a silver salt emulsion layer.

14. The method as set forth in claim 11, wherein steps (C) and (D) are simultaneously performed such that the wirings and the guard line are made of the same material.

15. The method as set forth in claim 11, wherein in step (D), the guard line is formed so as to be spaced apart from the wirings.

16. The method as set forth in claim 11, wherein in step (D), the guard line is formed so as to be electrically connected to the wirings.
